(19) United States
(12) Patent Application Publication
(10) Pub. No.: US 2011/0169736 A1
(43) Pub. Date: Jul. 14, 2011

(54) INTERACTIVE INPUT SYSTEM AND TOOL TRAY THEREFOR

(75) Inventors: Stephen Patrick Bolt, Stittsville (CA); Trevor Mitchell Akitt, Calgary (CA); Cheng Guo, Calgary (CA); Sean Thompson, Calgary (CA)

(73) Assignee: SMART Technologies ULC, Calgary (CA)

(21) Appl. No.: 12/709,424

(22) Filed: Feb. 19, 2010

Related U.S. Application Data
(60) Provisional application No. 61/294,831, filed on Jan. 13, 2010.

(51) Int. Cl. G06F 3/033; H05K 7/00

(52) U.S. Cl. 345/158; 361/679.4

(57) ABSTRACT

An interactive input system comprises an interactive surface and a tool tray supporting at least one tool to be used to interact with the interactive surface. The tool tray comprises processing structure for communicating with at least one imaging device and processing data received from the at least one imaging device for locating a pointer positioned in proximity with the interactive surface.

### CROSS REFERENCE TO RELATED APPLICATIONS

This application claims the benefit of U.S. Provisional Application No. 61/294,831 to Bolt, et al., filed on Jan. 13, 2010, entitled “INTERACTIVE INPUT SYSTEM AND TOOL TRAY THEREFOR”, the content of which is incorporated herein by reference in its entirety.

### FIELD OF THE INVENTION

The present invention relates generally to interactive input systems, and in particular to an interactive input system and a tool tray therefor.

### BACKGROUND OF THE INVENTION

Interactive input systems that allow users to inject input (e.g., digital ink, mouse events, etc.) into an application program using an active pointer (e.g., a pointer that emits light, sound or other signal), a passive pointer (e.g., a finger, cylinder or other object) or other suitable input device such as for example, a mouse or trackball, are well known. These interactive input systems include but are not limited to: touch systems comprising touch panels employing analog resistive or machine vision technology to register pointer input such as those disclosed in U.S. Pat. Nos. 5,448,263; 6,141,000; 6,337,681; 6,747,636; 6,803,906; 7,232,986; 7,236,162; 7,274,356; and 7,532,206 assigned to SMART Technologies ULC of Calgary, Alberta, Canada, assignee of the subject application, the contents of which are incorporated by reference in their entirety; touch systems comprising touch panels employing electromagnetic, capacitive, acoustic or other technologies to register pointer input; tablet personal computers (PCs); laptop PCs; personal digital assistants (PDAs); and other similar devices.

Above-incorporated U.S. Pat. No. 6,803,906 to Morrison, et al., discloses a touch system that employs machine vision to detect pointer interaction with a touch surface on which a computer-generated image is presented. A rectangular bezel or frame surrounds the touch surface and supports digital imaging devices at its corners. The digital imaging devices have overlapping fields of view that encompass and look generally across the touch surface. The digital imaging devices acquire images looking across the touch surface from different vantages and generate image data. Image data acquired by the digital imaging devices is processed by on-board digital signal processors to determine if a pointer exists in the captured image data. When it is determined that a pointer exists in the captured image data, the digital signal processors convey pointer characteristic data to a master controller, which in turn processes the pointer characteristic data to determine the location of the pointer in (x,y) coordinates relative to the touch surface using triangulation. The pointer coordinates are conveyed to a computer executing one or more application programs. The computer uses the pointer coordinates to update the computer-generated image that is presented on the touch surface. Pointer contacts on the touch surface can therefore be recorded as writing or drawing or used to control execution of application programs executed by the computer.

U.S. Pat. No. 7,532,206 to Morrison, et al., discloses a touch system and method that differentiates between passive pointers used to contact a touch surface so that pointer position data generated in response to a pointer contact with the touch surface can be processed in accordance with the type of pointer used to contact the touch surface. The touch system comprises a touch surface to be contacted by a passive pointer and at least one imaging device having a field of view looking generally across the touch surface. At least one processor communicates with the at least one imaging device and analyzes images acquired by the at least one imaging device to determine the type of pointer used to contact the touch surface and the location on the touch surface where pointer contact is made. The determined type of pointer and the location on the touch surface where the pointer contact is made are used by a computer to control execution of an application program executed by the computer.

In order to determine the type of pointer used to contact the touch surface, a curve of growth method is employed to differentiate between different pointers. During this method, a horizontal intensity profile (HIP) is formed by calculating a sum along each row of pixels in each acquired image thereby to produce a one-dimensional profile having a number of points equal to the row dimension of the acquired image. A curve of growth is then generated from the HIP by forming the cumulative sum from the HIP.

Many models of interactive whiteboards sold by SMART Technologies ULC of Calgary, Alberta, Canada under the name SMARTBoard™ that employ machine vision technology to register pointer input have a tool tray mounted below the interactive whiteboard that comprises receptacles or slots for holding a plurality of pen tools as well as an eraser tool. These tools are passive devices without power source or electronics. When a tool is removed from its slot in the tool tray, a sensor in the tool tray detects the removal of that tool allowing the interactive whiteboard to determine that the tool has been selected. SMARTBoard™ software processes the next contact with the interactive whiteboard surface as an action from the tool that previously resided in that particular slot. Once a pen tool is removed from its slot, users can write in the color assigned to the selected pen tool, or with any other pointer such as a finger or other object. Similarly, when the eraser tool is removed from its slot in the tool tray, the software processes the next contact with the interactive whiteboard surface as an erasing action, whether the contact is from the eraser, or from another pointer such as a finger or other object. Additionally, below the tool tray two buttons are provided. One of the buttons, when pressed, allows the user to execute typical “right click” mouse functions, such as copy, cut, paste, select all, and the like, while the other button when pressed calls up an onscreen keyboard for allowing users to enter text, numbers, and the like. Although this existing tool tray provides satisfactory functionality, it is desired to improve and expand upon such functionality.

It is therefore an object of the present invention at least to provide a novel interactive input system and a tool tray therefor.

### SUMMARY OF THE INVENTION

Accordingly, in one aspect there is provided an interactive input system comprising an interactive surface; and a tool tray supporting at least one tool to be used to interact with said interactive surface, said tool tray comprising processing structure for communicating with at least one imaging device and processing data received from said at least one imaging device for locating a pointer positioned in proximity with said interactive surface.

In one embodiment, the tool tray is configured to receive at least one detachable module for communicating with the processing structure. The at least one detachable module is any of a communications module for enabling communication with an external computer, an accessory module, a power accessory module and peripheral device module. The communications module may comprise a communications interface selected from the group consisting of Wi-Fi, Bluetooth, RS-232 and Ethernet. The at least one detachable module may further comprise at least one USB port.

In one embodiment, the tool tray further comprises at least one indicator for indicating an attribute of pointer input and/or at least one button for allowing selection of an attribute of pointer input.

In another aspect, there is provided a tool tray for an interactive input system comprising at least one imaging device capturing images of a region of interest, the tool tray comprising a housing having an upper surface configured to support one or more tools, said housing accommodating processing structure communicating with the at least one imaging device and processing data received therefrom for locating a pointer positioned in proximity with the region of interest.

In still another aspect, there is provided a tool tray for an interactive input system comprising at least one device for detecting a pointer brought into proximity with a region of interest, the tool tray comprising a housing having an upper surface configured to support one or more tools, said housing accommodating processing structure communicating with the at least one imaging device and processing data received therefrom for locating a pointer positioned in proximity with the region of interest.

### BRIEF DESCRIPTION OF THE DRAWINGS

Embodiments will now be described more fully with reference to the accompanying drawings in which:

FIG. 1 is a schematic, partial perspective view of an interactive input system.

FIG. 2 is a block diagram of the interactive input system of FIG. 1.

FIG. 3 is a block diagram of an imaging assembly forming part of the interactive input system of FIG. 1.

FIGS. 4a and 4b are front and rear perspective views of a housing assembly forming part of the imaging assembly of FIG. 3.

FIG. 5 is a block diagram of a master controller forming part of the interactive input system of FIG. 1.

FIG. 6a is a simplified exemplary image frame captured by the imaging assembly of FIG. 3 when IR LEDs associated when other imaging assemblies of the interactive input system are in an off state.

FIG. 6b is a simplified exemplary image frame captured by the imaging assembly of FIG. 3 when IR LEDs associated when other imaging assemblies of the interactive input system are in a low current on state.

FIG. 7 is a perspective view of a tool tray forming part of the interactive input system of FIG. 1.

FIGS. 8a and 8b are top plan views of the tool tray of FIG. 7 showing accessory modules in attached and detached states, respectively.

FIG. 9 is an exploded perspective view of the tool tray of FIG. 7.

FIG. 10 is a top plan view of circuit card arrays for use with the tool tray of FIG. 7.

FIGS. 11a and 11b are upper and lower perspective views, respectively, of a power button module for use with the tool tray of FIG. 7.

FIG. 12 is a perspective view of a dummy communications module for use with the tool tray of FIG. 7.

FIG. 13 is a side view of an eraser tool for use with the tool tray of FIG. 7.

FIGS. 14a and 14b are perspective views of the eraser tool of FIG. 13 in use, showing erasing of large and small areas, respectively.

FIG. 15 is a side view of a prior art eraser tool.

FIGS. 16a and 16b are simplified exemplary image frames captured by the imaging assembly of FIG. 3 including the eraser tools of FIGS. 13 and 15, respectively.

FIGS. 17a to 17d are top plan views of the tool tray of FIG. 7, showing wireless, RS-232, and USB communications modules, and a projector adapter module, respectively, attached thereto.

FIG. 18 is a perspective view of a tool tray accessory module for use with the tool tray of FIG. 7.

FIG. 19 is a top plan view of another embodiment of a tool tray for use with the interactive input system of FIG. 1.

FIG. 20 is a top plan view of yet another embodiment of a tool tray for use with the interactive input system of FIG. 1.

FIGS. 21a to 21c are top plan views of still yet another embodiment of a tool tray for use with the interactive input system of FIG. 1.

FIG. 22 is a side view of another embodiment of an eraser tool.

FIG. 23 is a side view of yet another embodiment of an eraser tool.

### DETAILED DESCRIPTION OF THE EMBODIMENTS

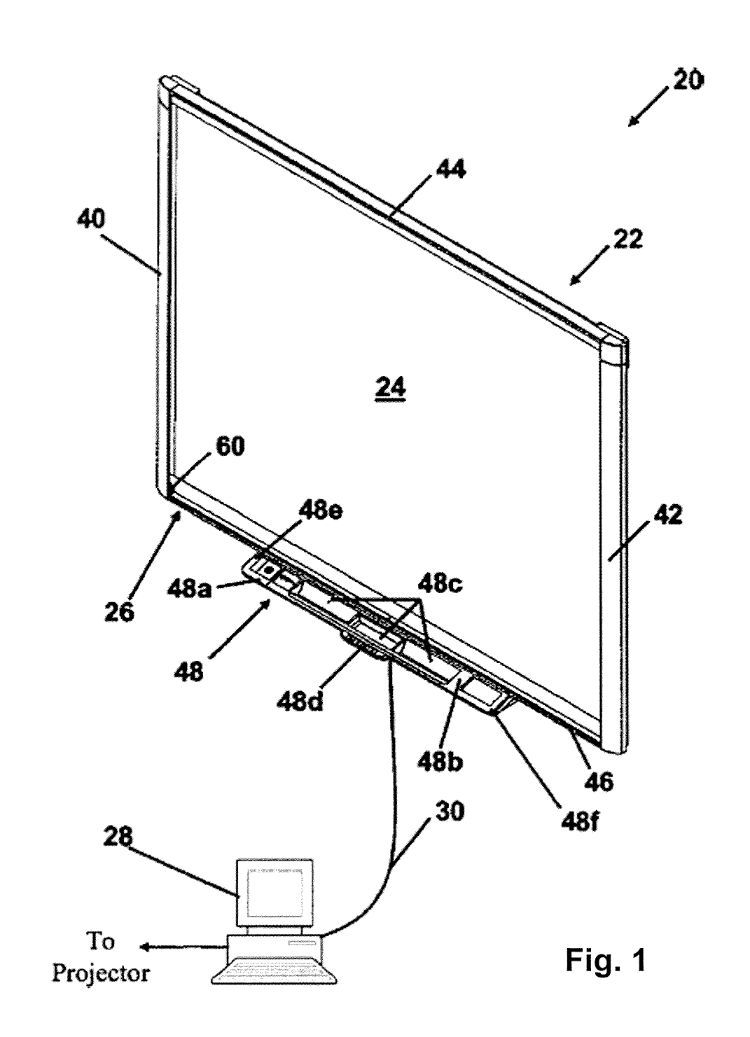

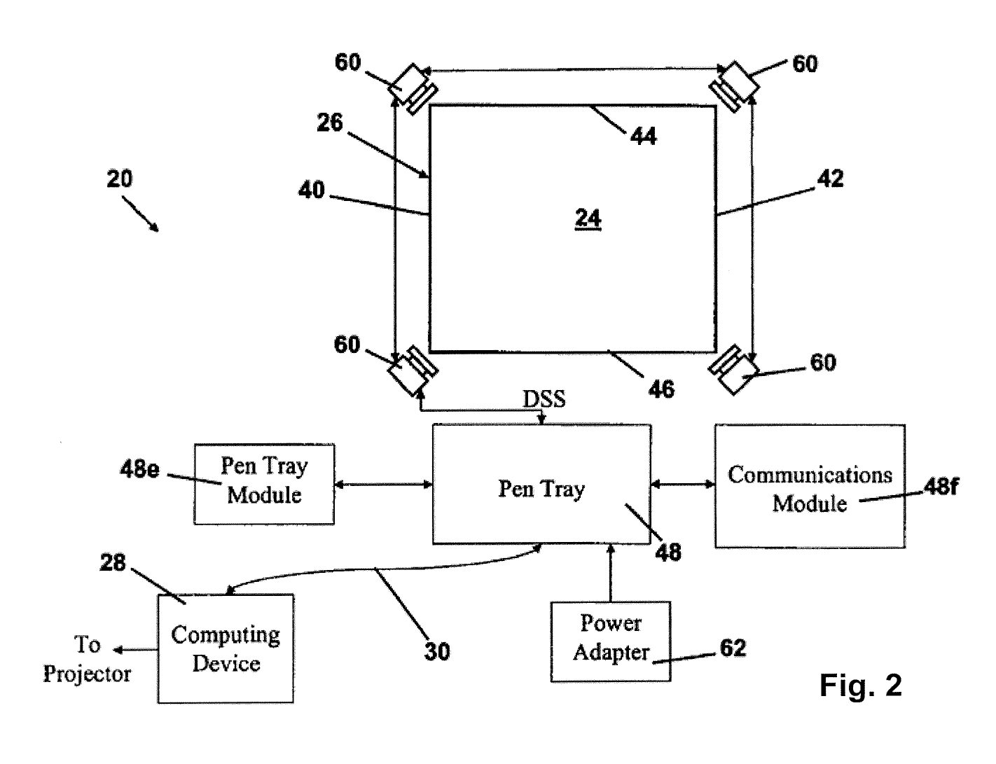

Turning now to FIGS. 1 and 2, an interactive input system that allows a user to inject input such as digital ink, mouse events etc. into an application program executed by a computing device is shown and is generally identified by reference numeral 20. In this embodiment, interactive input system 20 comprises an interactive board 22 mounted on a vertical support surface such as for example, a wall surface or the like. Interactive board 22 comprises a generally planar, rectangular interactive surface 24 that is surrounded about its periphery by a bezel 26. An ultra-short throw projector (not shown) such as that sold by SMART Technologies ULC under the name Miata™ is also mounted on the support surface above the interactive board 22 and projects an image, such as for example a computer desktop, onto the interactive surface 24.

The interactive board 22 employs machine vision to detect one or more pointers brought into a region of interest in proximity with the interactive surface 24. The interactive board 22 communicates with a general purpose computing device 28 executing one or more application programs via a universal serial bus (USB) cable 30. General purpose computing device 28 processes the output of the interactive board 22 and adjusts image data that is output to the projector, if required, so that the image presented on the interactive surface 24 reflects pointer activity. In this manner, the interactive board 22, general purpose computing device 28 and projector allow pointer activity proximate to the interactive surface 24 to be recorded as writing or drawing or used to control execution of one or more application programs executed by the general purpose computing device 28.

The bezel 26 in this embodiment is mechanically fastened to the interactive surface 24 and comprises four bezel segments 40, 42, 44, 46. Bezel segments 40 and 42 extend along opposite side edges of the interactive surface 24 while bezel segments 44 and 46 extend along the top and bottom edges of the interactive surface 24 respectively. In this embodiment, the inwardly facing surface of each bezel segment 40, 42, 44 and 46 comprises a single, longitudinally extending strip or band of retro-reflective material. To take best advantage of the properties of the retro-reflective material, the bezel segments 40, 42, 44 and 46 are oriented so that their inwardly facing surfaces extend in a plane generally normal to the plane of the interactive surface 24.

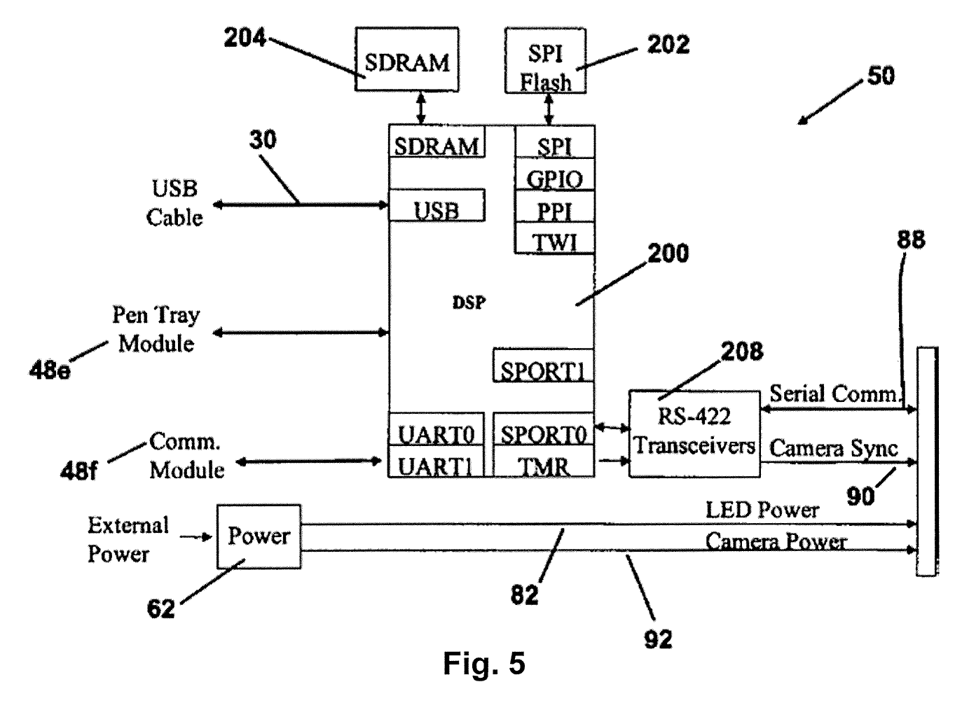

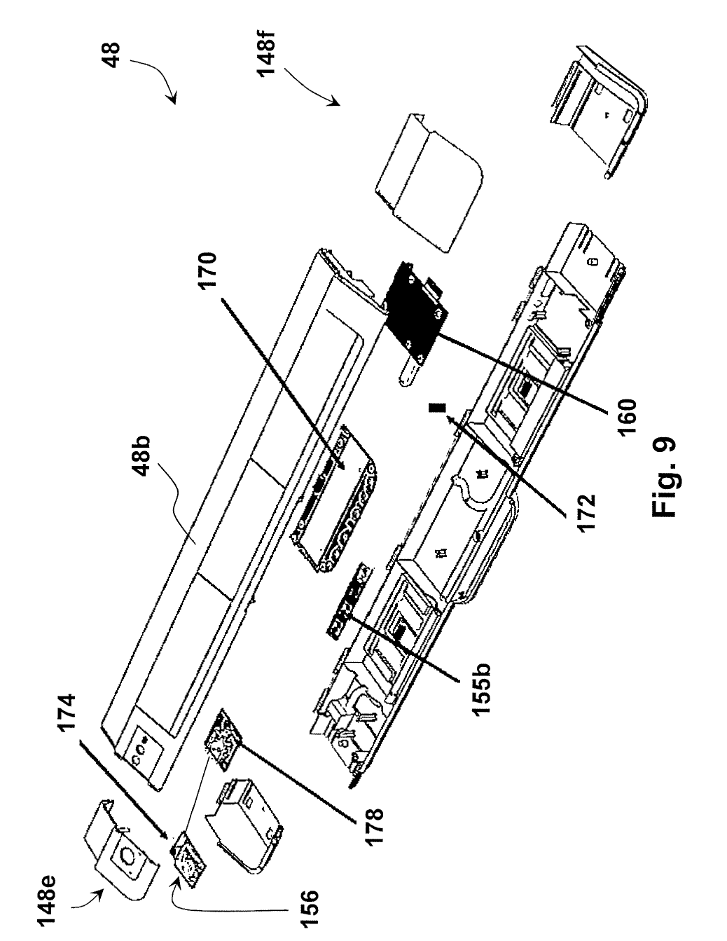

A tool tray 48 is affixed to the interactive board 22 adjacent the bezel segment 46 using suitable fasteners such as for example, screws, clips, adhesive etc. As can be seen, the tool tray 48 comprises a housing 48a having an upper surface 48b configured to define a plurality of receptacles or slots 48c. The receptacles 48c are sized to receive one or more pen tools P as well as an eraser tool 152 (see FIGS. 8a and 8b) that can be used to interact with the interactive surface 24. Control buttons 48d are provided on the upper surface 48b of the housing 48a to enable a user to control operation of the interactive input system 20. One end of the tool tray 48 is configured to receive a detachable tool tray accessory module 48e while the opposite end of the tool tray 48 is configured to receive a detachable communications module 48f for remote device communications. The housing 48a accommodates a master controller 50 (see FIG. 5) as will be described.

Imaging assemblies 60 are accommodated by the bezel 26, with each imaging assembly 60 being positioned adjacent a different corner of the bezel. The imaging assemblies 60 are oriented so that their fields of view overlap and look generally across the entire interactive surface 24. In this manner, any pointer such as for example a user's finger, a cylinder or other suitable object, or a pen or eraser tool lifted from a receptacle 48c of the tool tray 48, that is brought into proximity of the interactive surface 24 appears in the fields of view of the imaging assemblies 60. A power adapter 62 provides the necessary operating power to the interactive board 22 when connected to a conventional AC mains power supply.

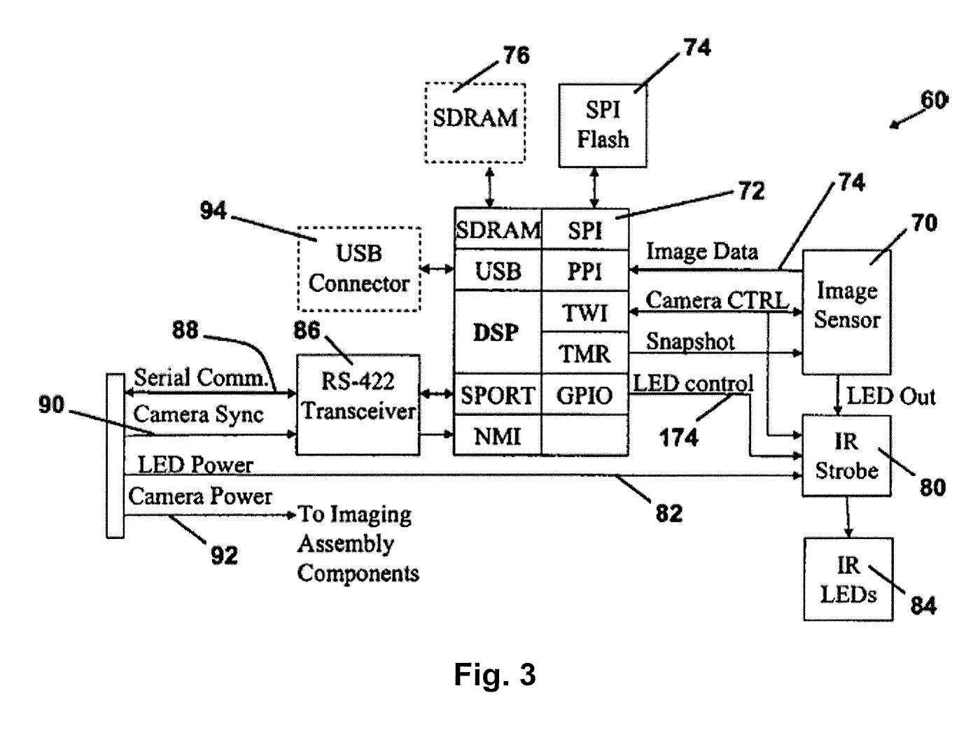

Turning now to FIG. 3, one of the imaging assemblies 60 is better illustrated. As can be seen, the imaging assembly 60 comprises an image sensor 70 such as that manufactured by Aptina (Micron) MT9V034 having a resolution of 752×480 pixels, fitted with a two element, plastic lens (not shown) that provides the image sensor 70 with a field of view of approximately 104 degrees. In this manner, the other imaging assemblies 60 are within the field of view of the image sensor 70 thereby to ensure that the field of view of the image sensor 70 encompasses the entire interactive surface 24.

A digital signal processor (DSP) 72 such as that manufactured by Analog Devices under part number ADSP-BF522 Blackfin or other suitable processing device, communicates with the image sensor 70 over an image data bus 74 via a parallel port interface (PPI). A serial peripheral interface (SPI) flash memory 74 is connected to the DSP 72 via an SPI port and stores the firmware required for image assembly operation. Depending on the size of captured image frames as well as the processing requirements of the DSP 72, the imaging assembly 60 may optionally comprise synchronous dynamic random access memory (SDRAM) 76 to store additional temporary data as shown by the dotted lines. The image sensor 70 also communicates with the DSP 72 via a two-wire interface (TWI) and a timer (TMR) interface. The control registers of the image sensor 70 are written from the DSP 72 via the TWI in order to configure parameters of the image sensor 70 such as the integration period for the image sensor 70.

In this embodiment, the image sensor 70 operates in snapshot mode. In the snapshot mode, the image sensor 70, in response to an external trigger signal received from the DSP 72 via the TMR interface that has a duration set by a timer on the DSP 72, enters an integration period during which an image frame is captured. Following the integration period after the generation of the trigger signal by the DSP 72 has ended, the image sensor 70 enters a readout period during which time the captured image frame is available. With the image sensor in the readout period, the DSP 72 reads the image frame data acquired by the image sensor 70 over the image data bus 74 via the PPI. The frame rate of the image sensor 70 in this embodiment is between about 900 and about 960 frames per second. The DSP 72 in turn processes image frames received from the image sensor 72 and provides pointer information to the master controller 50 at a reduced rate of approximately 120 points/sec. Those of skill in the art will however appreciate that other frame rates may be employed depending on the desired accuracy of pointer tracking and whether multi-touch and/or active pointer identification is employed.

Three strobe circuits 80 communicate with the DSP 72 via the TWI and via a general purpose input/output (GPIO) interface. The IR strobe circuits 80 also communicate with the image sensor 70 and receive power provided on LED power line 82 via the power adapter 52. Each strobe circuit 80 drives a respective illumination source in the form of an infrared (IR) light emitting diode (LED) 84a to 84c that provides infrared backlighting over the interactive surface 24. Further specifics concerning the strobe circuits 80 and their operation are described in U.S. Provisional Application Ser. No. 61/294,825 to Akin entitled “INTERACTIVE INPUT SYSTEM AND ILLUMINATION SYSTEM THEREFOR” filed on even Jan. 13, 2010, the content of which is incorporated herein by reference in its entirety.

The DSP 72 also communicates with an RS-422 transceiver 86 via a serial port (SPORT) and a non-maskable interrupt (NMI) port. The transceiver 86 communicates with the master controller 50 over a differential synchronous signal (DSS) communications link 88 and a synch line 90. Power for the components of the imaging assembly 60 is provided on power line 92 by the power adapter 52. DSP 72 may also optionally be connected to a USB connector 94 via a USB port as indicated by the dotted lines. The USB connector 94 can be used to connect the imaging assembly 60 to diagnostic equipment.

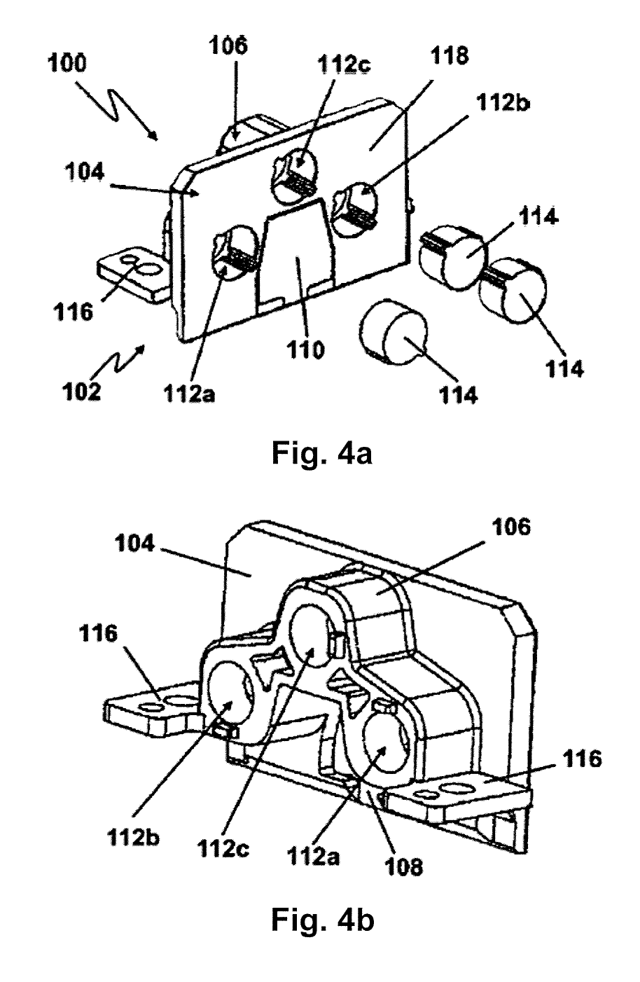

The image sensor 70 and its associated lens as well as the IR LEDs 84a to 84c are mounted on a housing assembly 100 that is best illustrated in FIGS. 4a and 4b. As can be seen, the housing assembly 100 comprises a polycarbonate housing body 102 having a front portion 104 and a rear portion 106 extending from the front portion. An imaging aperture 108 is centrally formed in the housing body 102 and accommodates an IR-pass/visible light blocking filter 110. The filter 110 has an IR-pass wavelength range of between about 830 nm and about 880 nm. The image sensor 70 and associated lens are positioned behind the filter 110 and oriented such that the field of view of the image sensor 70 looks through the filter 110 and generally across the interactive surface 24. The rear portion 106 is shaped to surround the image sensor 70. Three passages 112a to 112c are formed through the housing body 102. Passages 112a and 112b are positioned on opposite sides of the filter 110 and are in general horizontal alignment with the image sensor 70. Passage 112c is centrally positioned above the filter 110. Each tubular passage receives a light source socket 114 that is configured to receive a respective one of the IR LEDs 84. In particular, the socket 114 received in passage 112a accommodates IR LED 84a, the socket 114 received in passage 112b accommodates IR LED 84b, and the socket 114 received in passage 112c accommodates IR LED 84c. Mounting flanges 116 are provided on opposite sides of the rear portion 106 to facilitate connection of the housing assembly 100 to the bezel 26 via suitable fasteners. A label 118 formed of retro-reflective material overlies the front surface of the front portion 104. Further specifics concerning the housing assembly and its method of manufacture are described in U.S. Provisional Application Ser. No. 61/294,827 to Liu, et al., entitled “HOUSING ASSEMBLY FOR INTERACTIVE INPUT SYSTEM AND FABRICATION METHOD” filed on Jan. 13, 2010, the content of which is incorporated herein by reference in its entirety.

The master controller 50 better is illustrated in FIG. 5. As can be seen, master controller 50 comprises a DSP 200 such as that manufactured by Analog Devices under part number ADSP-BF522 Blackfin or other suitable processing device. A serial peripheral interface (SPI) flash memory 202 is connected to the DSP 200 via an SPI port and stores the firmware required for master controller operation. A synchronous dynamic random access memory (SDRAM) 204 that stores temporary data necessary for system operation is connected to the DSP 200 via an SDRAM port. The DSP 200 communicates with the general purpose computing device 28 over the USB cable 30 via a USB port. The DSP 200 communicates through its serial port (SPORT) with the imaging assemblies 60 via an RS-422 transceiver 208 over the differential synchronous signal (DSS) communications link 88. In this embodiment, as more than one imaging assembly 60 communicates with the master controller DSP 200 over the DSS communications link 88, time division multiplexed (TDM) communications is employed. The DSP 200 also communicates with the imaging assemblies 60 via the RS-422 transceiver 208 over the camera synch line 90. DSP 200 communicates with the tool tray accessory module 48e over an inter-integrated circuit I²C channel and communicates with the communications accessory module 48f over universal asynchronous receiver/transmitter (UART), serial peripheral interface (SPI) and I²C channels.

As will be appreciated, the architectures of the imaging assemblies 60 and master controller 50 are similar. By providing a similar architecture between each imaging assembly 60 and the master controller 50, the same circuit board assembly and common components may be used for both thus reducing the part count and cost of the interactive input system 20. Differing components are added to the circuit board assemblies during manufacture dependent upon whether the circuit board assembly is intended for use in an imaging assembly 60 or in the master controller 50. For example, the master controller 50 may require a SDRAM 76 whereas the imaging assembly 60 may not.

The general purpose computing device 28 in this embodiment is a personal computer or other suitable processing device comprising, for example, a processing unit, system memory (volatile and/or non-volatile memory), other non-removable or removable memory (e.g., a hard disk drive, RAM, ROM, EEPROM, CD-ROM, DVD, flash memory, etc.) and a system bus coupling the various computer components to the processing unit. The computer may also comprise a network connection to access shared or remote drives, one or more networked computers, or other networked devices.

During operation, the DSP 200 of the master controller 50 outputs synchronization signals that are applied to the synch line 90 via the transceiver 208. Each synchronization signal applied to the synch line 90 is received by the DSP 72 of each imaging assembly 60 via transceiver 86 and triggers a non-maskable interrupt (NMI) on the DSP 72. In response to the non-maskable interrupt triggered by the synchronization signal, the DSP 72 of each imaging assembly 60 ensures that its local timers are within system tolerances and if not, corrects its local timers to match the master controller 50. Using one local timer, the DSP 72 initiates a pulse sequence via the snapshot line that is used to condition the image sensor to the snapshot mode and to control the integration period and frame rate of the image sensor 70 in the snapshot mode. The DSP 72 also initiates a second local timer that is used to provide output on the LED control line 174 so that the IR LEDs 84a to 84c are properly powered during the image frame capture cycle.

In response to the pulse sequence output on the snapshot line, the image sensor 70 of each imaging assembly 60 acquires image frames at the desired image frame rate. In this manner, image frames captured by the image sensor 70 of each imaging assembly can be referenced to the same point of time allowing the position of pointers brought into the fields of view of the image sensors 70 to be accurately triangulated. Also, by distributing the synchronization signals for the imaging assemblies 60, electromagnetic interference is minimized by reducing the need for transmitting a fast clock signal to each image assembly 60 from a central location. Instead, each imaging assembly 60 has its own local oscillator (not shown) and a lower frequency signal (e.g., the point rate, 120 Hz) is used to keep the image frame capture synchronized.

During image frame capture, the DSP 72 of each imaging assembly 60 also provides output to the strobe circuits 80 to control the switching of the IR LEDs 84a to 84c so that the IR LEDs are illuminated in a given sequence that is coordinated with the image frame capture sequence of each image sensor 70. In particular, in the sequence the first image frame is captured by the image sensor 70 when the IR LED 84c is fully illuminated in a high current mode and the other IR LEDs are off. The next image frame is captured when all of the IR LEDs 84a to 84c are off. Capturing these successive image frames with the IR LED 84c on and then off allows ambient light artifacts in captured image frames to be cancelled by generating difference image frames as described in U.S. Application Publication No. 2009/0278794 to McReynolds, et al., assigned to SMART Technologies ULC, the content of which is incorporated herein by reference in its entirety. The third image frame is captured by the image sensor 70 when only the IR LED 84a is on and the fourth image frame is captured by the image sensor 70 when only the IR LED 84b is on. Capturing these image frames allows pointer edges and pointer shape to be determined as described in U.S. Provisional Application No. 61/294,832 to McGibney, et al., entitled “INTERACTIVE INPUT SYSTEM AND ILLUMINATION SYSTEM THEREFOR” filed on Jan. 14, 2010, the contents of which is incorporated herein by reference in its entirety. The strobe circuits 80 also control the IR LEDs 84a to 84c to inhibit blooming and to reduce the size of dark regions in captured image frames that are caused by the presence of other imaging assemblies 60 within the field of view of the image sensor 70 as will now be described.

During the image capture sequence, when each IR LED 84 is on, the IR LED floods the region of interest over the interactive surface 24 with infrared illumination. Infrared illumination that impinges on the retro-reflective bands of bezel segments 40, 42, 44 and 46 and on the retro-reflective labels 118 of the housing assemblies 100 is returned to the imaging assemblies 60. As a result, in the absence of a pointer, the image sensor 70 of each imaging assembly 60 sees a bright band having a substantially even intensity over its length together with any ambient light artifacts. When a pointer is brought into proximity with the interactive surface 24, the pointer occludes infrared illumination reflected by the retro-reflective bands of bezel segments 40, 42, 44 and 46 and/or the retro-reflective labels 118. As a result, the image sensor 70 of each imaging assembly 60 sees a dark region that interrupts the bright band 159 in captured image frames. The reflections of the illuminated retro-reflective bands of bezel segments 40, 42, 44 and 46 and the illuminated retro-reflective labels 118 appearing on the interactive surface 24 are also visible to the image sensor 70.

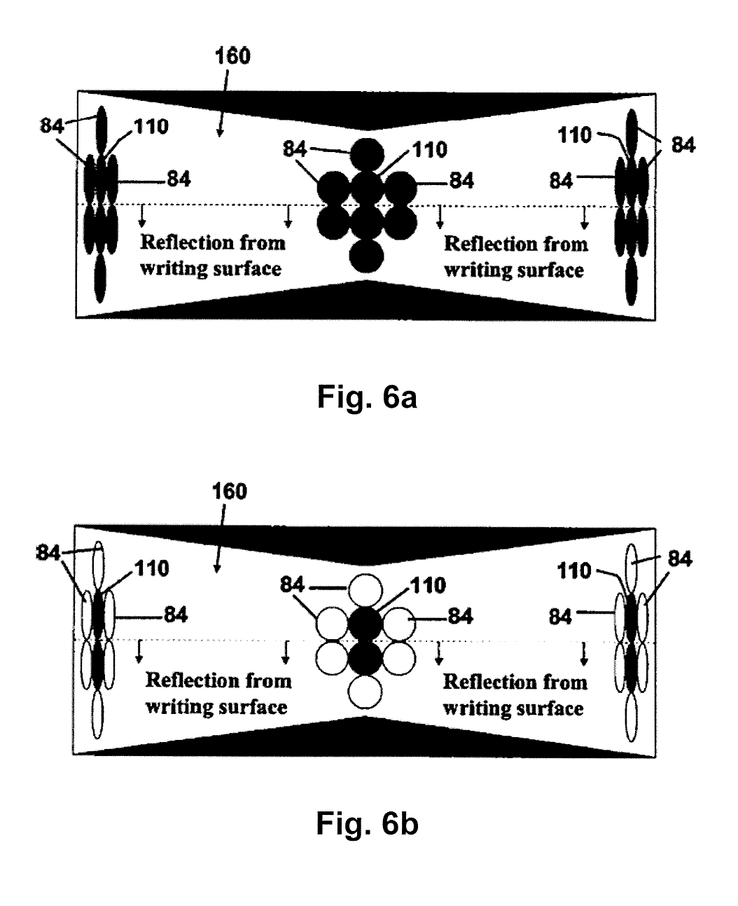

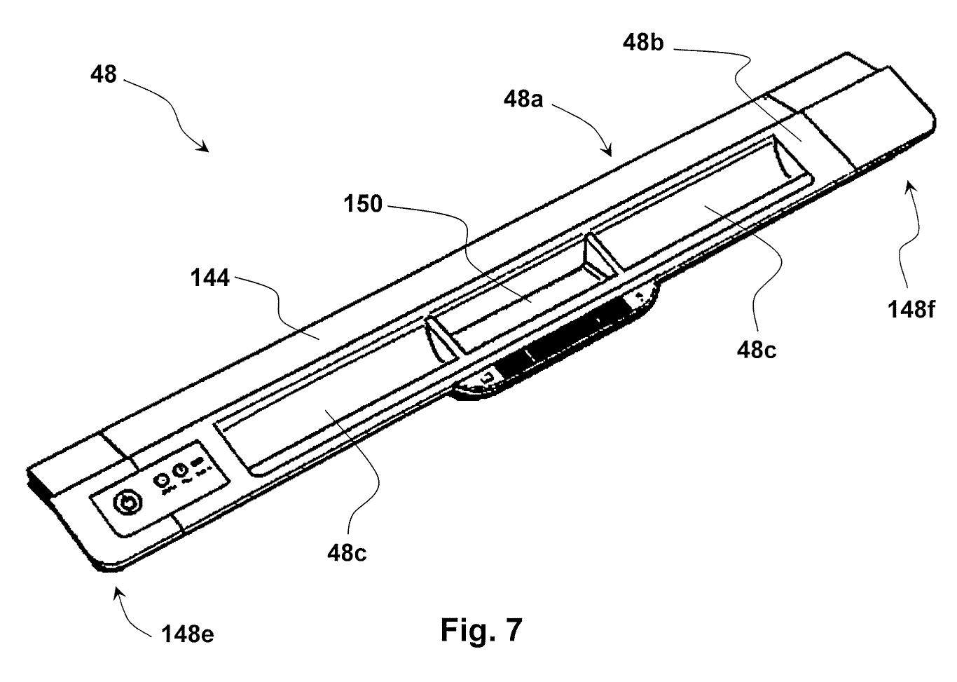

FIG. 6a shows an exemplary image frame captured by the image sensor 70 of one of the imaging assemblies 60 when the IR LEDs 84 associated with the other imaging assemblies 60 are off during image frame capture. As can be seen, the IR LEDs 84a to 84c and the filter 110 of the other imaging assemblies 60 appear as dark regions that interrupt the bright band 159. These dark regions can be problematic as they can be inadvertently recognized as pointers.

To address this problem, when the image sensor 70 of one of the imaging assemblies 60 is capturing an image frame, the strobe circuits 80 of the other imaging assemblies 60 are conditioned by the DSPs 72 to a low current mode. In the low current mode, the strobe circuits 80 control the operating power supplied to the JR LEDs 84a to 84c so that they emit infrared lighting at an intensity level that is substantially equal to the intensity of reflected illumination reflected by the retro-reflective bands on the bezel segments 40, 42, 44 and 46 and by the retro-reflective labels 118. FIG. 6b shows an exemplary image frame captured by the image sensor 70 of one of the imaging assemblies 60 when the IR LEDs 84a to 84c associated with the other imaging assemblies 60 are operated in the low current mode. As a result, the size of each dark region is reduced. Operating the IR LEDs 84a to 84c in this manner also inhibits blooming (i.e., saturation of image sensor pixels) which can occur if the IR LEDs 84a to 84c of the other imaging assemblies 60 are fully on during image frame capture. The required levels of brightness for the IR LEDs 84a to 84c in the low current mode are related to the distance between the image sensor 70 and the opposing bezel segments 40, 42, 44, and 46. Generally, lower levels of brightness are required as the distance between the image sensor 70 and the opposing bezel segments 40, 42, 44, and 46 increases due to the light loss within the air as well as inefficient distribution of light from each IR LED towards the bezel segments 40, 42, 44, and 46.

The sequence of image frames captured by the image sensor 70 of each imaging assembly 60 is processed by the DSP 72 to identify each pointer in each image frame and to obtain pointer shape and contact information as described in above-incorporated U.S. Provisional Application Ser. No. 61/294,832 to McGibney, et al. The DSP 72 of each imaging assembly 60 in turn conveys the pointer data to the DSP 200 of the master controller 50. The DSP 200 uses the pointer data received from the DSPs 72 to calculate the position of each pointer relative to the interactive surface 24 in (x,y) coordinates using well known triangulation as described in above-incorporated U.S. Pat. No. 6,803,906 to Morrison. This pointer coordinate data along with pointer shape and pointer contact status date is conveyed to the general purpose computing device 28 allowing the image data presented on the interactive surface 24 to be updated.

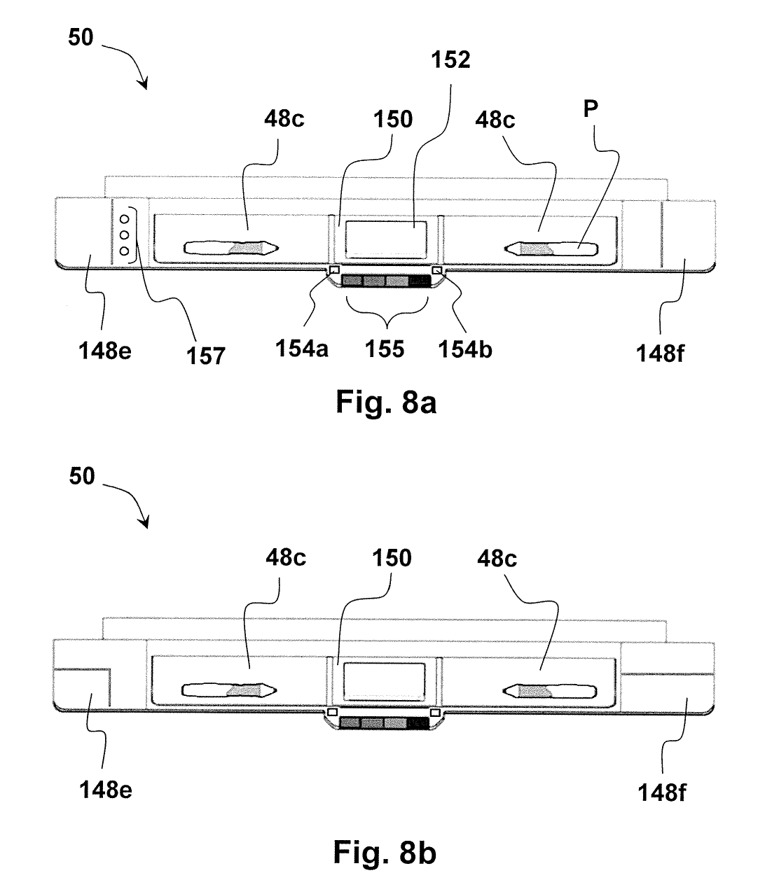

Turning now to FIGS. 7 to 12, the tool tray 48 is better illustrated. As can be seen, tool tray comprises a housing 48a that encloses a generally hollow interior in which several circuit card arrays (CCAs) are disposed. As mentioned previously, one end of the tool tray 48 is configured to receive a detachable tool tray accessory module 48e while the opposite end is configured to receive a detachable communications module 48f for remote device communications, as illustrated in FIGS. 8a and 8b. In the embodiment shown in FIGS. 7 to 12, the housing 48a of tool tray 48 has a power button module 148e and a dummy module 148f attached thereto. However, other accessory modules may alternatively be connected to the housing 48a of the tool tray 48 to provide different functionality, as will be described below. Additionally, tool tray 48 has a rear portion 144 defining a generally planar mounting surface that is shaped for abutting against an underside of the interactive board 22, and thereby provides a surface for the tool tray 48 to be mounted to the interactive board. In this embodiment, upper surface 48b defines two receptacles or slots 48c configured to each support a respective pen tool P, and a slot 150 configured to support a respective eraser tool 152.

Tool tray 48 has a set of buttons for allowing user selection of an attribute of pointer input. In the embodiment shown, there are six attribute buttons 154 and 155 positioned centrally along the front edge of body 130. Each of the attribute buttons 154 and 155 permits a user to select a different attribute of pointer input. In this embodiment, the two outermost buttons 154a and 154b are assigned to left mouse-click and right mouse-click functions, respectively, while attribute buttons 155a, 155b, 155c, and 155d are assigned to black, blue, green and red input colour, respectively.

Tool tray 48 is equipped with a main power button 156 which, in this embodiment, is housed within the power button module 148e. Power button 156 controls the on/off status of the interactive input system 20, together with any accessories connected the interactive input system 20, such as, for example, the projector (not shown). As will be appreciated, power button 156 is positioned at an intuitive, easy-to-find location and therefore allows a user to switch the interactive input system 20 on and off in a facile manner. Tool tray 48 also has a set of assistance buttons 157 positioned near an end of the housing 48a for enabling a user to request help from the interactive input system. In this embodiment, assistance buttons 157 comprise an “orient” button 157a and a “help” button 157b.

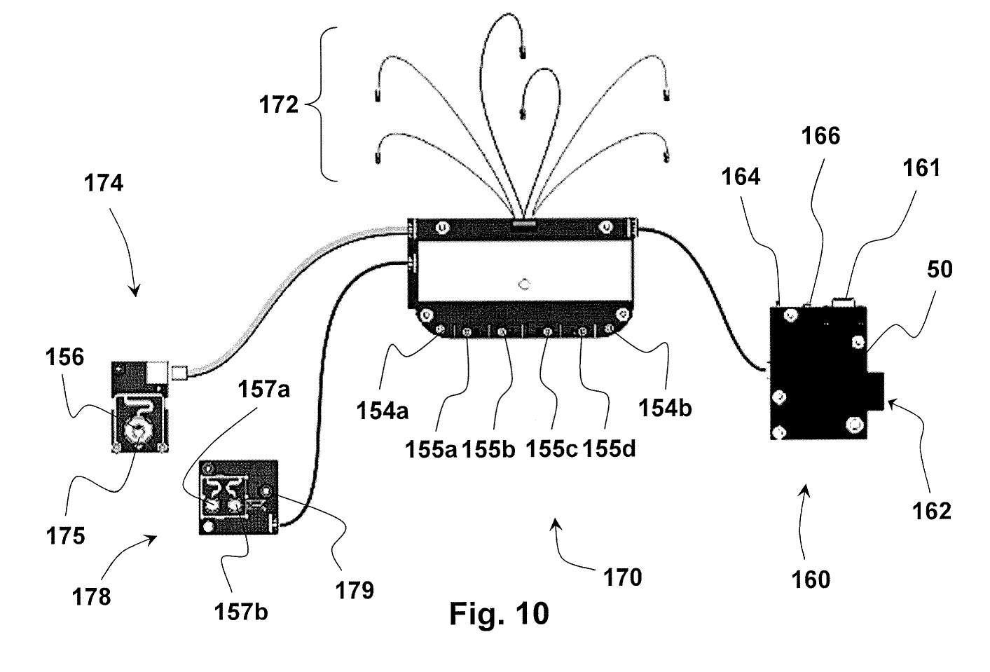

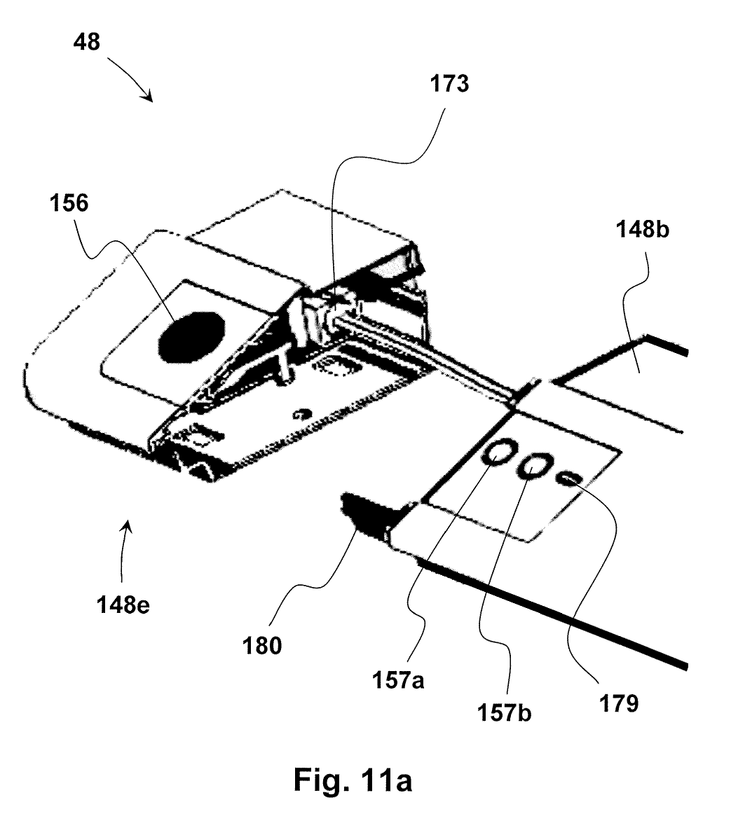

The internal components of tool tray 48 may be more clearly seen in FIGS. 9 and 10. As mentioned previously, the interior of housing 48a accommodates a plurality of CCAs each supporting circuitry associated with the functionality of the tool tray 48. Main controller board 160 supports the master controller 50, which generally controls the overall functionality of the tool tray 48. Main controller board 160 also comprises USB connector 94 (not shown in FIGS. 8 and 9), and a data connection port 161 for enabling connection to the imaging assemblies 60. Main controller board 160 also has an expansion connector 162 for enabling connection to a communications module 48f. Main controller board 160 additionally has a power connection port 164 for enabling connection to power adapter 62, and an audio output port 166 for enabling connection to one or more speakers (not shown).

Main controller board 160 is connected to an attribute button control board 170, on which attribute buttons 154 and 155 are mounted. Attribute button control board 170 further comprises a set of four light emitting diodes (LEDs) 171a to 171d. In this embodiment, each LED is housed within a respective colour button 155a to 155d, and is used to indicate the activity status of each colour button 155. Accordingly, in this embodiment, LEDs 171a to 171d are white, blue, green and red in colour, respectively. Attribute button control board 170 also comprises tool sensors 172. The tool sensors 172 are grouped into three pairs, with each pair being mounted as a set within a respective receptacle 48c or receptacle 150 for detecting the presence of a tool within that receptacle. In this embodiment, each pair of sensors 172 comprises an infrared transmitter and receiver, whereby tool detection occurs by interruption of the infrared signal across the slot.

Attribute button control board 170 is in turn linked to a connector 173 for enabling removable connection to a power module board 174, which is housed within the interior of power button module 148e. Power module board 174 has the power button 156 physically mounted thereon, together with an LED 175 contained within the power button 156 for indicating power on/off status.

Attribute button control board 170 is also connected to an assistance button control board 178, on which “orient” button 157a and “help” button 157b are mounted. A single LED 179 is associated with the set of buttons 157a and 157b for indicating that one of buttons has been depressed.

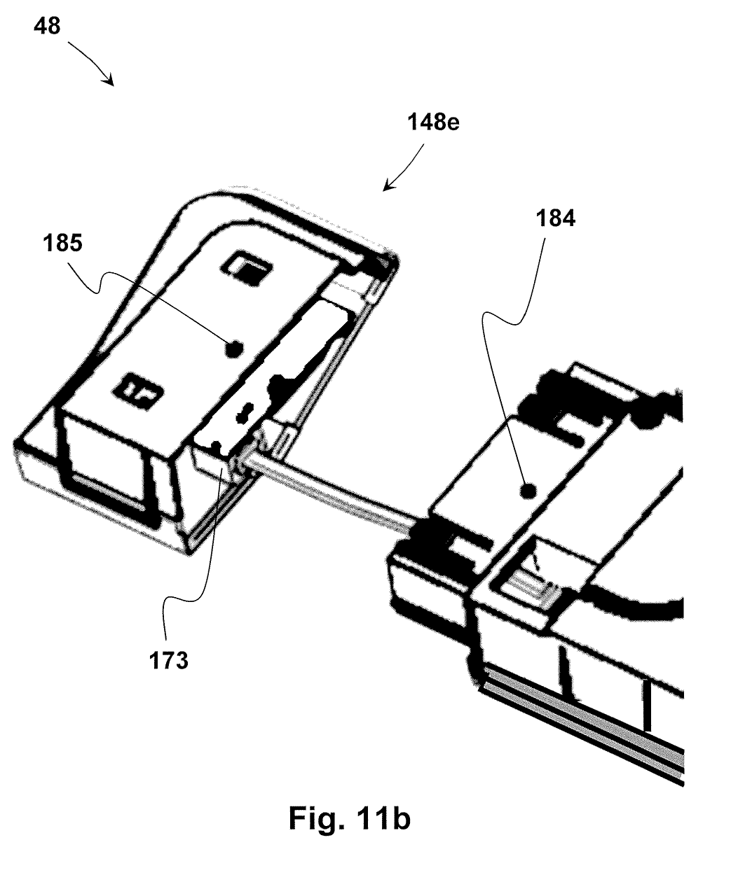

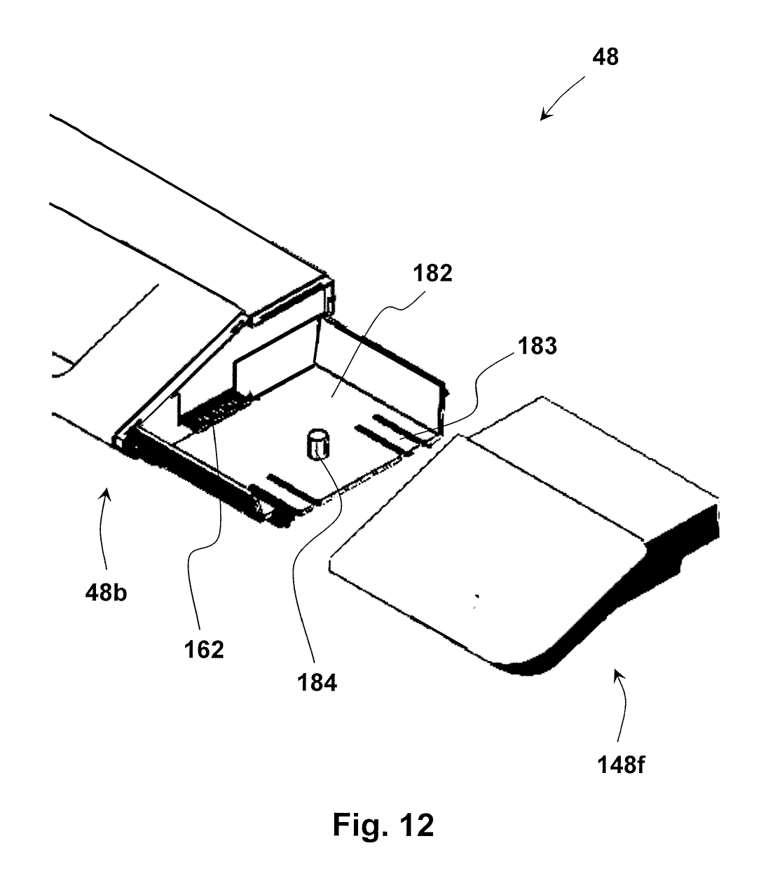

Housing 48a comprises a protrusion 180 at each of its ends for enabling the modules to be mechanically attached thereto. As is better illustrated in FIGS. 11a, 11b and FIG. 12, protrusion 180 is shaped to engage the interior of the modules 48e and 48f in an abutting male-female relationship. Protrusion 180 has two clips 183, each for cooperating with a suitably positioned tab (not shown) within the base of each of the modules 148e and 148f. Additionally, protrusion 180 has a bored post 184 positioned to cooperate with a corresponding aperture 185 formed in the base of each of the modules 48e and 48f, allowing modules 48e and 48f to be secured to housing 48a by fasteners.

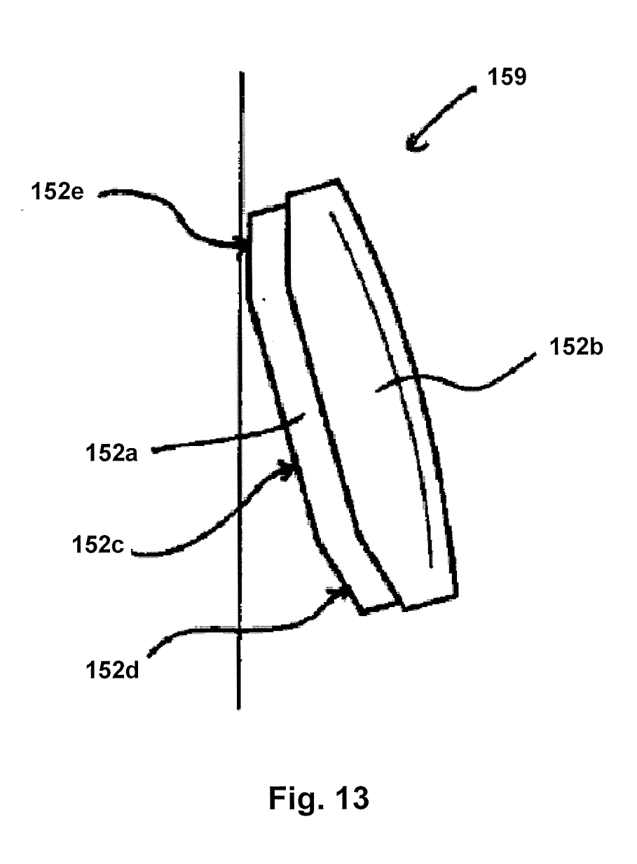

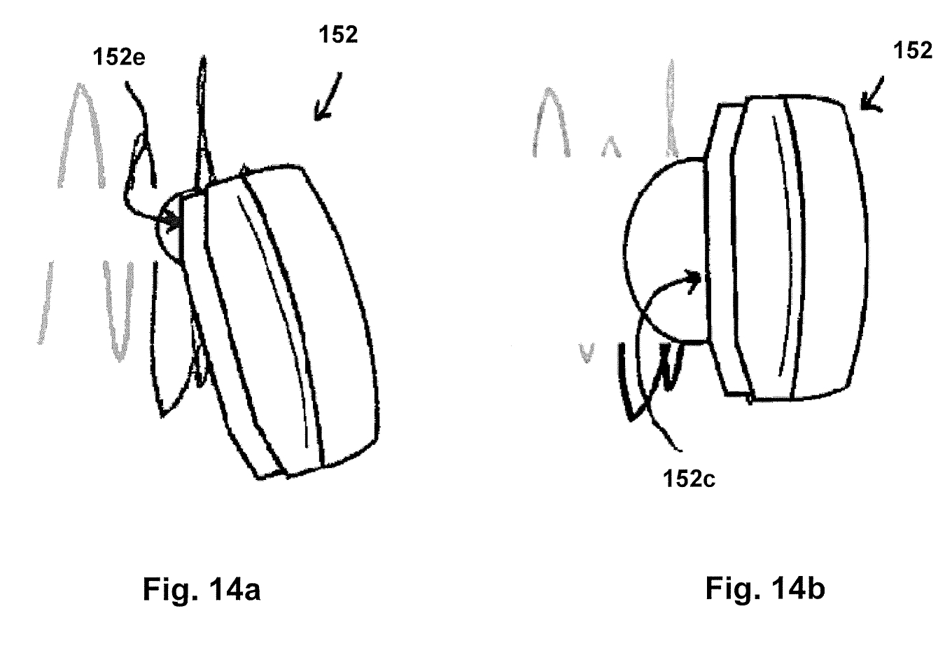

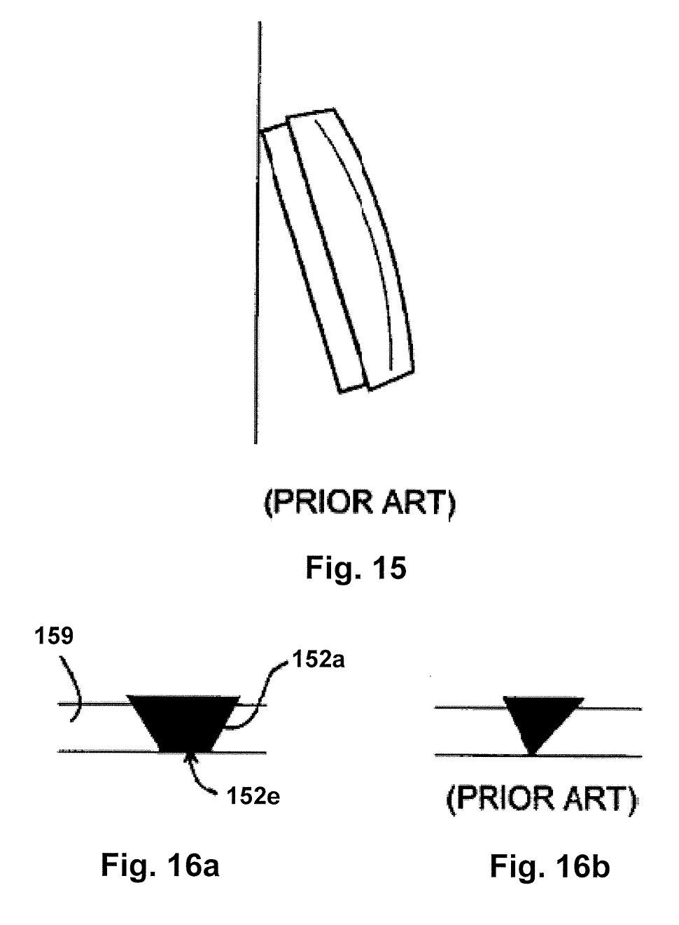

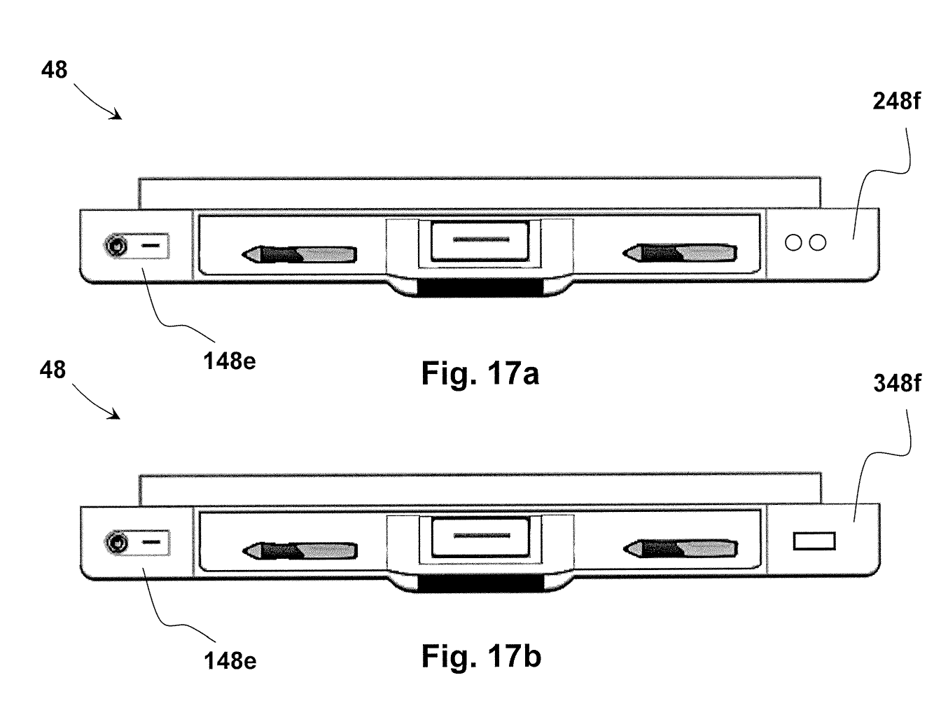

The eraser tool 152 is best illustrated in FIG. 13. As can be seen, eraser tool 152 has an eraser pad 152a attached to a handle 152b that is sized to be gripped by a user. In this embodiment, eraser pad 152a has a main erasing surface 152c and two faceted end surfaces 152d. The inclusion of both a main erasing surface 152c and faceted end surfaces 152d allows eraser tool 152 to be used for erasing areas of different sizes in a facile manner, as illustrated FIGS. 14a and 14b. Additionally, faceted end surfaces 152d provide narrow surfaces for detailed erasing of smaller areas, but which are wide enough to prevent the eraser tool 152 from being inadvertently recognized as a pointer tool during processing of image frames acquired by the imaging assemblies 60, as shown in FIG. 16a. As will be appreciated, this provides an advantage over prior art eraser tools such as that illustrated in FIG. 15, which are sometimes difficult to discern from a pointer tip during processing of image frames acquired by the imaging assemblies, as shown in FIG. 16b.

The positioning of the master controller 50 and the associated electronics in the interior of tool tray 48 provides the advantage of easy user accessibility for the attachment of accessories to the interactive input system 20. Such accessories can include, for example, a module for wireless communication with one or more external devices. These external devices may include, for example, a user's personal computer configured for wireless communication, such as a portable “laptop” computer, or one or more wireless student response units, or any other device capable of wireless communication. Such accessories can alternatively include, for example, a communication module for non-wireless (i.e., “wired”) communication with one or more external devices, or with a peripheral input device. As will be appreciated, the need to interface with such devices may vary throughout the lifetime of the interactive input system 20. By conveniently providing removable accessories for the tool tray 48, the user is able to modify or update the functionality of the tool tray in a facile manner and without having instead to replace the entire tool tray or the entire interactive input system. Additionally, if, in the unlikely event, a component within one of the accessory modules were to fail, replacement of the defective component by the end user would be readily possible without the assistance of a professional installer and/or without returning the entire interactive input system to the manufacturer. Also, as frame assemblies typically comprise metal, the positioning of a wireless communication interface in the tool tray 48 reduces any interference that may otherwise occur when connecting such an adapter behind the interactive board, as in prior configurations. Additionally, the positioning of the attachment points for accessory modules at the ends of the tool tray 48 permits accessories of large size to be connected, as needed.

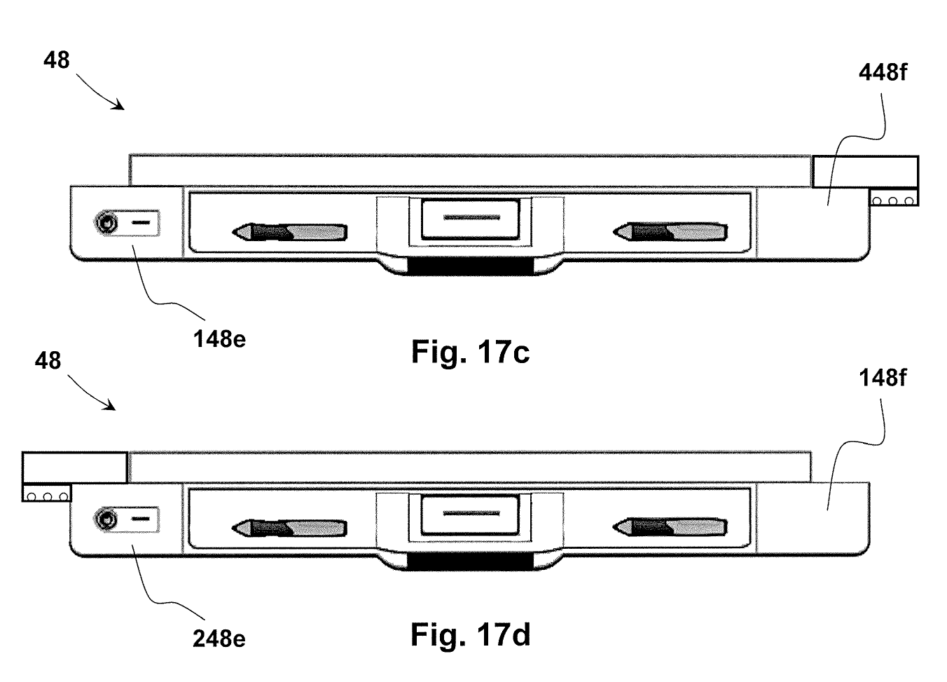

The accessory modules permit any of a wide range of functions to be added to the tool tray 48. For example, FIGS. 17a to 17c show a variety of communications modules for use with tool tray 48, and which may be used to enable one or more external computers or computing devices (e.g., smart phones, tablets, storage devices, cameras, etc.) to be connected to the interactive input system 20. FIG. 17a shows a wireless communications module 248f connected to the housing 48a of tool tray 48. Wireless communications module 248f allows one or more external computers such as, for example, a user's personal computer, to be connected to the interactive input system 20 for the purpose of file sharing or screen sharing, for example, or to allow student response systems to be connected to the system while the general purpose computing device 28 runs student assessment software, for example. FIG. 17b shows an RS-232 connection module 348f for enabling a wired connection between the tool tray 48 and an external computer or computing device. FIG. 17c shows a USB communication module 448f having a plurality of USB ports, for enabling a wired USB connection between the tool tray 48 and one or more external computers, a peripheral devices, USB storage devices, and the like.

The accessory modules are not limited to extending communications capabilities of the tool tray 48. For example, FIG. 17d shows a projector adapter module 248e connected to the housing 48a of tool tray 48. Projector adapter module 248e enables tool tray 48 to be connected to an image projector, and thereby provides an interface for allowing the user to remotely control the on/off status of the projector. Projector adapter module 248e also includes indicator lights and a text display for indicating status events such as projector start-up, projector shut-down, projector bulb replacement required, and the like. Still other kinds of accessory modules are possible for use with tool tray 48, such as, for example, extension modules comprising additional tool receptacles, or extension modules enabling the connection of other peripheral input devices, such as cameras, printers, or other interactive tools such as rulers, compasses, painting tools, music tools, and the like.

In use, tool tray 48 enables an attribute of pointer input to be selected by a user in a more intuitive and easy-to-use manner than prior interactive input systems through the provision of attribute selection buttons 154 and 155, together with colour attribute button indicator LEDs 171a to 171d. A user may therefore render an input attribute (a red colour, for example) active by depressing attribute button 155d, which may for example cause LED 171d associated with that button to blink or to remain in an illuminated state. Depressing the same button again would make the attribute inactive, which cancels any status indication provided by the LED, and which causes the input attribute to revert to a default value (a black colour, for example). Alternatively, the pointer attribute may be selectable from a software toolbar as presented on the interactive surface 24, whereby a button (not shown) on the tool tray 48 could be used to direct the general purpose computing device 28 to display such a menu.

Tool tray 48 also provides functionality for cases when more than one user is present. Here, sensors 172 can be used to monitor the presence of one or more pen tools within receptacles 48c. When multiple pen tools are detected to be absent, the interactive input system 20 presumes there are multiple users present and can be configured to launch a split-screen mode. Such split-screen modes are described in U.S. Patent Application Ser. No. 61/220,573 to Popovich, et al., entitled “MULTIPLE INPUT ANALOG RESISTIVE TOUCH PANEL AND METHOD OF MAKING SAME”, filed on Jun. 25, 2009, and assigned to SMART Technologies ULC, the content of which is incorporated herein by reference in its entirety. Here, the attribute for each pen tool and any other pointers may be selected using the selection buttons 154 and 155. In this case, the selected attribute is applied to all pointers on both split-screens. Alternatively, each split-screen may have a respective software tool bar for allowing attribute selection, and this selected pointer attribute can be applied to all pointer activity within the respective side of the split-screen and may be used to override any attribute information selected using buttons 154 and 155. The selection of an attribute from the software toolbar cancels any status indication provided by the LED. Similarly, if a common attribute (e.g., the colour blue) is selected from the respective software toolbar on both screens, the blue status indicator LED is activated.

The pointer attribute selection capabilities provided by tool tray 48 are not limited to input by pen tools associated with receptacles 48c, and may be applied to other pointers (e.g., a finger) used with the interactive input system 20. Additionally, a pointer attribute selected using any of attribute buttons 154 and 155 may be applied to input from any pointer (e.g., a finger, a tennis ball) while the pen tools are present within the receptacles 48c. Such a mode can be useful for users with special needs, for example. This mode of operation may be enabled by depressing an attribute button 154 and 155 and then bringing the pointer into proximity with interactive surface 24, and may be reset by upon removal of a pen tool from its receptacle 48c.

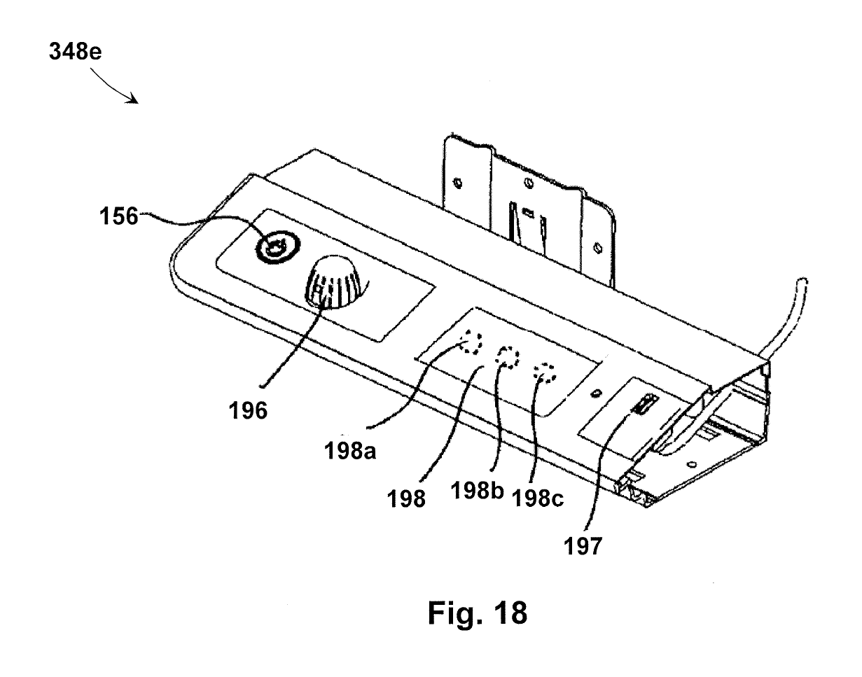

FIG. 18 shows another tool tray accessory module for use with the tool tray 48, generally indicated by reference numeral 348e. Accessory module 348e comprises a colour LCD touch screen 195, a volume control dial 196, together with a power button 156, and a USB port 197. Touch screen 195 provides a customizable interface that is configurable by the user for meeting a particular interactive input system requirement. The interface may be configured by the user as desired, for example depending on the type of other accessories connected to the tool tray 48, such as a wireless communications accessory. In the embodiment shown, touch screen 195 displays three buttons selectable to the user, namely a button 198a to enable the switching between video inputs, a button 198b for bringing up controls for the projector settings, and a help button 198c for providing general assistance to the user for interactive input system operation.

Pressing the video switching control button 198a results in the list of available video inputs to the projector being to be displayed on touch screen 184. For example, these may be identified simply as VGA, HDMI, composite video, component video, and so forth, depending on the type of video input. If the projector has more than one particular type of video input, these could be enumerated as VGA1, VGA2, for example. Alternatively, the touch screen 195 could display a list of particular types of devices likely to be connected to those video ports. For example, one input could be referred to as “Meeting Room PC”, while another could be referred to as “Guest Laptop”, etc. Selecting a particular video input from the list of available video inputs displayed causes a video switching accessory (not shown) installed in the tool tray 48 to change to that video input. Here, the video switching accessory would have input ports (not shown) corresponding to various formats of video input, such as VGA, HDMI, composite video, component video, and the like, for allowing the connection of laptops, DVD players, VCRs, Bluray players, gaming machines such as Sony Playstation 3, Microsoft Xbox 360 or Nintendo Wii, and/or other various types of video/media devices to the interactive input system.

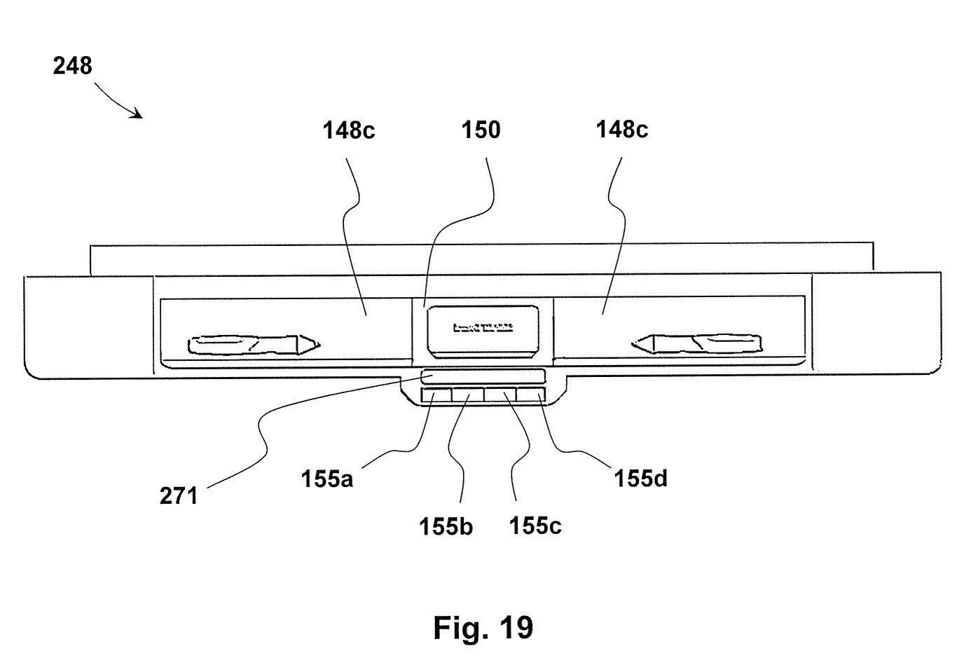

FIG. 19 shows another embodiment of a tool tray for use with the interactive input system 20, and generally indicated by reference numeral 248. Tool tray 248 is generally similar to the tool tray 48 described above with reference to FIGS. 6 to 12, except that it has a single indicator 271 for indicating the pointer colour status as selected using buttons 155a to 155d, as opposed to individual LEDs 171a to 171d associated with each of buttons 155a to 155d. Here, indicator 271 is made up of one or more multicolour LEDs, however those of skill in the art will appreciate that the indicator is not limited to this configuration and may instead be composed of a plurality of differently coloured LEDs sharing a common lens. The use of indicator 271 having a multicolour capability allows for a combination of the standard colours (namely black, blue, red and green) offered by buttons 155a to 155d to be displayed by indicator 271, and therefore allows a combination of the standard colours to be assigned as the input colour. Alternatively, the tool tray 248 could comprise a colour LCD screen, similar to that described with reference to FIG. 16, and the colour could thereby be chosen from a palette of colours presented on that LCD touch screen.

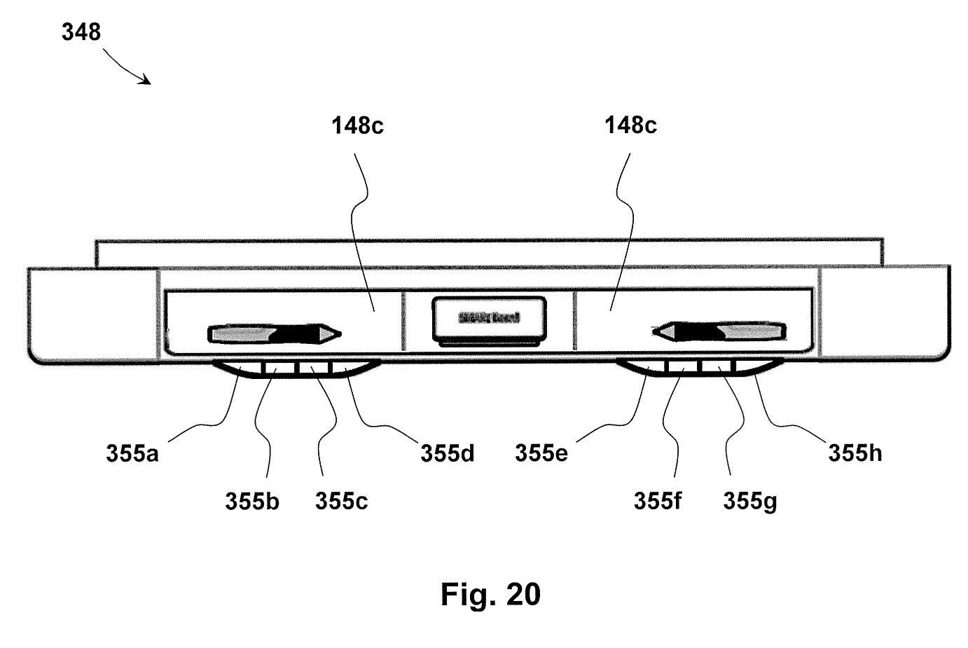

FIG. 20 shows still another embodiment of a tool tray for use with the interactive input system 20, and generally indicated by reference numeral 348. Tool tray 348 is again similar to the embodiments described above with reference to FIGS. 7 to 14, except that it has two sets of colour selection buttons 355 as opposed to a single set of buttons. Here, each set of buttons 355, namely buttons 355a to 355d and buttons 355e to 355h, is associated with a respective receptacle 148c. In the split screen mode, the colour of the input associated with each split screen may be selected by depressing one of the buttons 355 associated with that screen.

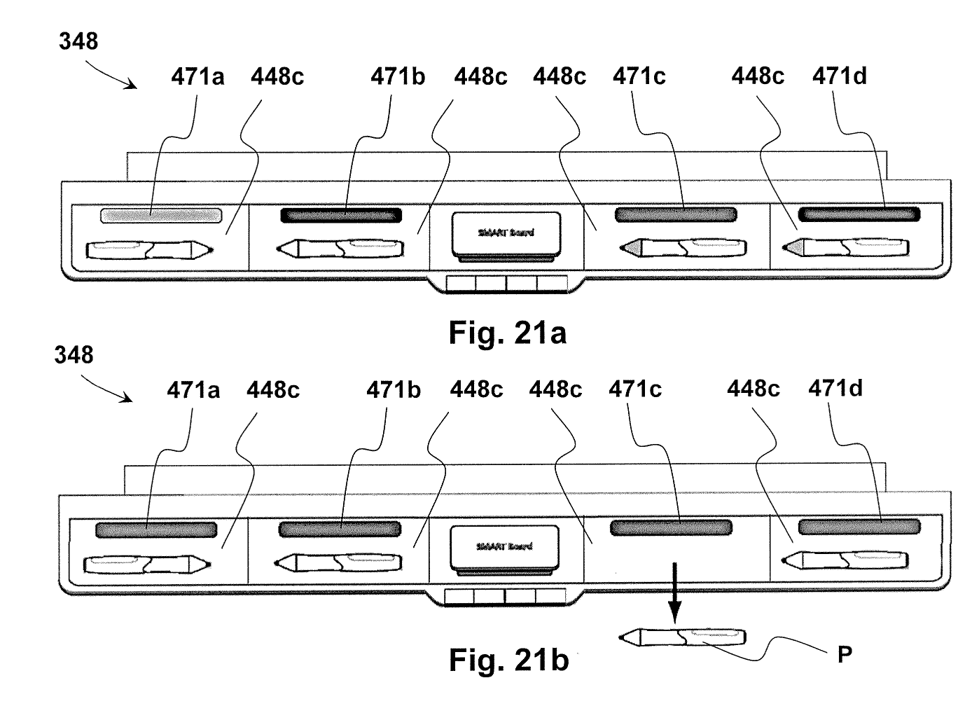

FIGS. 21a to 21c show still another embodiment of a tool tray for use with the interactive input system 20, and which is generally indicated by reference numeral 448. Tool tray 448 is generally similar to the embodiments described above with reference to FIGS. 7 to 14, except that it has four receptacles 448c each supporting a respective pen tool. Additionally, each receptable 448c has associated with it a single multicolour LED indicator 471a to 471d for indicating status of the attribute associated with the pen tool in that respective receptacle 448c. In the embodiment shown, the tool tray is configured such that indicators 471 display the colour status of each tool when all tools are in the receptacle 448c (FIG. 21a). When one tool is removed from its receptacle 448c (FIG. 21b), the colour of all of the tools is assigned the colour associated with the removed tool. In this configuration, depressing an attribute button 355 assigns the colour associated with that button 355 to all of the tools (FIG. 21c), which may be used to override any colour previously assigned to all of the tools, such as that in FIG. 21b.

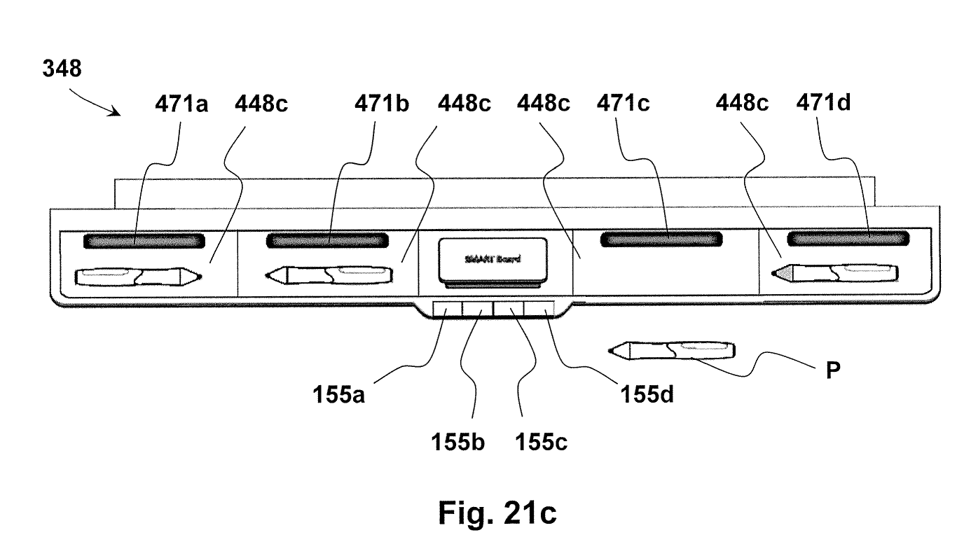

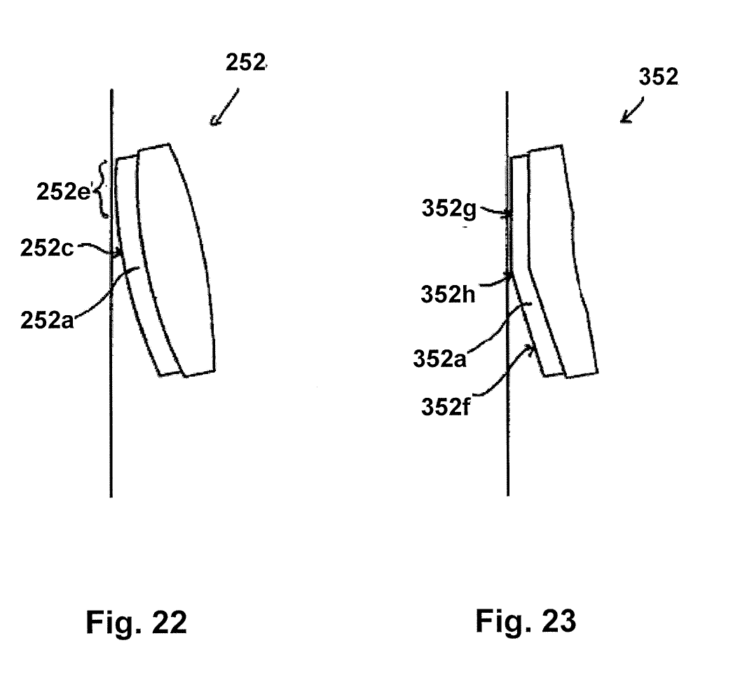

Although in embodiments described above, the eraser tool is described as having an eraser pad comprising a main erasing surface and faceted end surfaces, other configurations are possible. For example, FIG. 22 shows another embodiment of an eraser tool, generally indicated by reference number 252, having an eraser pad 252a with a generally rounded shape. This rounded shape of eraser pad 252a allows a portion 252e of erasing surface 252c to be used for erasing. As will be appreciated, portion 252e is narrow enough to allow eraser tool 252 to be used for detailed erasing, but is wide enough to allow eraser tool 252 to be discernable from a pointer tip, during processing of image frames acquired by the imaging assemblies 60. FIG. 23 shows yet another embodiment of an eraser tool, generally indicated by reference number 352, having an eraser pad 352a with a generally chevron shape. The chevron shape provides two main erasing surfaces 352f and 352g, which may each be used for erasing. Additionally, main erasing surfaces 352f and 352g are separated by a ridge 352h. As will be appreciated, ridge 352h is narrow enough to allow eraser tool 352 to be used for detailed erasing but is wide enough, owing to the large angle of the chevron shape, to allow eraser tool 352 to be discernable from a pointer tip, during processing of image frames acquired by the imaging assemblies 60.

In an alternative embodiment, the accessory modules may provide video input ports/USB ports to allow a guest to connect a laptop or other processing device to the interactive board 22. Further, connecting the guest laptop may automatically launch software from the accessory on the laptop to allow for complete functionality of the board.

Although in embodiments described above, the tool tray comprises buttons for inputting information, in other embodiments, the tool tray may comprise other features such as dials for inputting information.

Although in embodiments described above, the tool tray housing comprises attribute buttons, in other embodiments, the attribute buttons may instead be positioned on an accessory module.

Although in embodiments described above, the tool tray comprises one or more receptacles for supporting tools, in an alternative embodiment, an accessory module may comprise one or more receptacles. In this case, the accessory module can enable the interactive input system to operate with multipointer functionality and in a split screen mode.

Although in embodiments described above, the tool tray is located generally centrally along the bottom edge of the interactive board 22, in other embodiments, the tool tray may alternatively be located in another location relative to the interactive board, such as towards a side edge of the interactive board 22.

Although in embodiments described above, the interactive input system comprises one tool tray, in other embodiments, the interactive input system may comprise two or more tool trays positioned either on the same or on different sides of the interactive board 22.

In an alternative embodiment, the accessory modules may be configured to enable one or more other modules to be connected to it in series. Here, the modules may communicate in a serial or parallel manner with the master controller 50.

Although in embodiments described above, the interactive input system uses imaging assemblies for the detection of one or more pointers in proximity with a region of interest, in other embodiments, the interactive input may instead use another form of pointer detection. In such embodiment, the interactive input system may comprise an analog resistive touch surface, a capacitive-based touch surface etc.

In the embodiments described above, a short-throw projector is used to project an image onto the interactive surface 24. As will be appreciated other front projection devices or alternatively a rear projection device may be used to project the image onto the interactive surface 24. Rather than being supported on a wall surface, the interactive board 22 may be supported on an upstanding frame or other suitable support. Still alternatively, the interactive board 22 may engage a display device such as for example a plasma television, a liquid crystal display (LCD) device etc. that presents an image visible through the interactive surface 24.

Although a specific processing configuration has been described, those of skill in the art will appreciate that alternative processing configurations may be employed. For example, one of the imaging assemblies may take on the master controller role. Alternatively, the general purpose computing device may take on the master controller role.

Although embodiments have been described, those of skill in the art will appreciate that variations and modifications may be made with departing from the spirit and scope thereof as defined by the appended claims.

What is claimed is:

1. An interactive input system comprising:
an interactive surface; and
a tool tray supporting at least one tool to be used to interact with said interactive surface, said tool tray comprising processing structure for communicating with at least one imaging device and processing data received from said at least one imaging device for locating a pointer positioned in proximity with said interactive surface.

2. The interactive input system of claim 1, wherein the tool tray is configured to receive at least one detachable module for communicating with the processing structure.

3. The interactive input system of claim 2, wherein the at least one detachable module is any of a communications module for enabling communications with an external computer, an accessory module, a power accessory module, and a peripheral device module.

4. The interactive input system of claim 3, wherein the communications module comprises a communications interface selected from the group consisting of Wi-Fi, Bluetooth, RS-232, and Ethernet.

5. The interactive input system of claim 2, wherein the at least one detachable module further comprises at least one USB port.

6. The interactive input system of claim 2, wherein the tool tray further comprises at least one indicator for indicating an attribute of pointer input.

7. The interactive input system of claim 2, wherein the tool tray further comprises at least one button for allowing selection of an attribute of pointer input.

8. The interactive input system of claim 6, wherein the tool tray further comprises at least one button for allowing selection of the attribute of pointer input.

9. The interactive input system of claim 2, wherein the at least one tool comprises an eraser tool, said eraser tool comprising large area and small area erasing surfaces.

10. The interactive input system of claim 2, wherein the tool tray further comprises a sensor for detecting presence of the at least one tool.

11. The interactive input system of claim 2, wherein the tool tray further comprises a power switch.

12. The interactive input system of claim 10, wherein the at least one detachable module further comprises at least one indicator for indicating an attribute of pointer input.

13. The interactive input system of claim 12, wherein the module further comprises at least one button for allowing selection of the attribute of pointer input.

14. The interactive input system of claim 13, wherein the at least one tool comprises an eraser tool, said eraser tool comprising large area and small area erasing surfaces.

15. The interactive input system of claim 12, wherein the at least one module further comprises a power switch.

16. A tool tray for an interactive input system comprising at least one imaging device capturing images of a region of interest, the tool tray comprising:
a housing having an upper surface configured to support one or more tools, said housing accommodating processing structure communicating with the at least one imaging device and processing data received therefrom for locating a pointer positioned in proximity with the region of interest.

17. The tool tray of claim 16 configured to receive at least one detachable module for communicating with the processing structure.

18. The tool tray of claim 17, wherein the at least one detachable module is any one of a communications module for enabling communications with an external computer, an accessory module, a power accessory module, and a peripheral device module.

19. The tool tray of claim 18, wherein the communications module comprises a communications interface selected from the group consisting of Wi-Fi, Bluetooth, RS-232, and Ethernet.

20. The tool tray of claim 18, wherein the at least one detachable module further comprises at least one USB port.

21. The tool tray of claim 18, further comprising at least one indicator for indicating an attribute of pointer input.

22. The tool tray of claim 18, further comprising at least one button for allowing selection of the attribute of pointer input.

23. The tool tray of claim 18, wherein the at least one tool comprises an eraser tool, said eraser tool comprising large area and small area erasing surfaces.

24. The tool tray of claim 18, further comprising a sensor for detecting presence of the tool within the receptacle.

25. The tool tray of claim 18, further comprising a power switch.

26. The tool tray of claim 18, wherein the at least one detachable module further comprises at least one indicator for indicating an attribute of pointer input.

27. The tool tray of claim 26, wherein the at least one detachable module further comprises at least one button for allowing selection of the attribute of pointer input.

28. The tool tray of claim 27, wherein the at least one tool comprises an eraser tool, said eraser tool comprising large area and small area erasing surfaces.

29. The tool tray of claim 27, further comprising a sensor for detecting presence of the tool within the receptacle.

30. The tool tray of claim 29, wherein the at least one detachable module further comprises a power switch.

31. A tool tray for an interactive input system comprising at least one device for detecting a pointer brought into proximity with a region of interest, the tool tray comprising:
a housing having an upper surface configured to support one or more tools, said housing accommodating processing structure communicating with the at least one imaging device and processing data received therefrom for locating a pointer positioned in proximity with the region of interest.

32. The tool tray of claim 31 configured to receive at least one detachable module for communicating with the processing structure.

33. The tool tray of claim 32, wherein the at least one detachable module is any one of a communications module for enabling communications with an external computer, an accessory module, a power accessory module, and a peripheral device module.

34. The tool tray of claim 33, wherein the communications module comprises a communications interface selected from the group consisting of Wi-Fi, Bluetooth, RS-232, and Ethernet.

35. The tool tray of claim 33, wherein the at least one detachable module further comprises at least one USB port.

36. The tool tray of claim 33, further comprising at least one indicator for indicating an attribute of pointer input.

37. The tool tray of claim 36, further comprising at least one button for allowing selection of the attribute of pointer input.

38. The tool tray of claim 33, wherein the at least one tool comprises an eraser tool, said eraser tool comprising large area and small area erasing surfaces.

39. The tool tray of claim 33, further comprising a sensor for detecting presence of the tool within the receptacle.

40. The tool tray of claim 33, further comprising a power switch.

41. The tool tray of claim 39, wherein the at least one detachable module further comprises at least one indicator for indicating an attribute of pointer input.

42. The tool tray of claim 41, wherein the at least one detachable module further comprises at least one button for allowing selection of the attribute of pointer input.

43. The tool tray of claim 42, wherein the at least one tool comprises an eraser tool, said eraser tool comprising large area and small area erasing surfaces.

44. The tool tray of claim 42, wherein the at least one detachable module further comprises a power switch.
